(19) United States
(12) Patent Application Publication
(10) Pub. No.: US 2025/0247011 A1
(43) Pub. Date: Jul. 31, 2025

(54) POWER CONVERSION DEVICE

(71) Applicant: HITACHI, LTD., Tokyo (JP)

(72) Inventors: Kyota ASAI, Tokyo (JP); Akihiro NAMBA, Tokyo (JP); Norio ISHITSUKA, Tokyo (JP); Takeshi TOKUYAMA, Tokyo (JP)

(21) Appl. No.: 18/854,152

(22) PCT Filed: Apr. 27, 2023
(86) PCT No.: PCT/JP2023/016666

§ 371 Date: Oct. 4, 2024

(30) Foreign Application Priority Data
Jun. 14, 2022 (JP) 2022-095867

(51) Int. Cl. H02M 7/00; H05K 1/18; H05K 7/20

(52) U.S. Cl. CPC H02M 7/003; H05K 1/181; H05K 7/20927

(57) ABSTRACT

A power conversion device (100) includes: a plurality of power modules (201) which convert DC power into AC power; a DC wiring (22) which transmits DC power to the plurality of power modules (201); a circuit board (30) on which the plurality of power modules (201) are arranged and the DC wiring (22) is mounted; and a molding resin (23) which covers and seals the plurality of power modules (201) and the circuit board (30), in which the molding resin (23) has seal surface portions (231, 232) around the plurality of power modules (201), and the seal surface portions (231, 232) are thinner than regions sealing the plurality of power modules (201).

### TECHNICAL FIELD

The present invention relates to a power conversion device, and more particularly to, a power conversion device that supplies an alternating current to a motor for driving a hybrid vehicle or an electric vehicle.

### BACKGROUND ART

In recent years, concerning power conversion devices, there is a demand for an increase in output, and at the same time, there is also a demand for an improvement in manufacturability. In a case where a power conversion device includes power modules for three phases in which an upper arm circuit or a lower arm circuit for one phase is provided as one module, it is necessary to provide six modules. Therefore, it is important to improve the manufacturability of power modules.

On the other hand, an improvement in cooling performance as well as the improvement in manufacturability is also an important issue. If the cooling performance is low, an increase in output of the power conversion device is hindered. An in-vehicle power conversion device is used in an environment where a temperature change is larger than that of an industrial power conversion device. Therefore, there is a demand for a power conversion device capable of maintaining high reliability while being placed in a high-temperature environment.

A power conversion device described in PTL 1 includes a metal base, an insulating substrate disposed in a region excluding a peripheral edge portion on an upper surface of the metal base, a semiconductor element mounted on an upper surface of the insulating substrate, a resin case bonded to the peripheral edge portion on the upper surface of the metal base with an adhesive to surround a side surface of the semiconductor element, and a sealing resin filled in the resin case to seal the semiconductor element. A groove portion to be filled with the adhesive is formed in the peripheral edge portion on the upper surface of the metal base. According to such a configuration, even in a case where the resin case is thin, a leakage of the sealing resin and an occurrence of an insulation failure can be suppressed.

### CITATION LIST

### Patent Literature

PTL 1: JP 2021-111669 A

### SUMMARY OF INVENTION

### Technical Problem

In the power module (semiconductor device) described in PTL 1, the sealing resin for sealing the semiconductor element is covered with the metal base and the resin case, and the rigidity of the metal base and the resin case suppresses warping that occurs when the sealing resin is hardened at room temperature. However, in this structure, since the cooling is one-sided cooling in which the lower surface of the power module is adopted as a cooling surface, there is a problem that the cooling performance is low as compared with that in double-sided cooling in which both upper and lower surfaces of the power module are cooled.

An object of the present invention is to improve cooling performance by cooling both sides of a power module and to suppress warpage that occurs when a sealing resin is hardened at room temperature.

### Solution to Problem

A power conversion device according to one aspect of the present invention includes: a plurality of power modules which convert DC power into AC power; a DC wiring which transmits DC power to the plurality of power modules; a circuit board on which the plurality of power modules are arranged and the DC wiring is mounted; and a molding resin which covers and seals the plurality of power modules and the circuit board, in which the molding resin has seal surface portions around the plurality of power modules, and the seal surface portions are thinner than regions sealing the plurality of power modules.

### Advantageous Effects of Invention

The power conversion device according to the present invention is capable of improving cooling performance by cooling both sides of the power module, and suppressing warpage that occurs when the sealing resin is hardened at room temperature.

### BRIEF DESCRIPTION OF DRAWINGS

FIG. 1 is a schematic plan view illustrating a power conversion device according to a first embodiment of the present invention, in which a flow path forming body is omitted.

FIG. 2 is a schematic cross-sectional view illustrating the power conversion device according to the first embodiment of the present invention in a cross section taken along line A-A of FIG. 1.

FIG. 3 is a schematic plan view illustrating the power conversion device according to the first embodiment of the present invention, in which a molding resin omitted.

FIG. 4 is a schematic top view illustrating a first power module according to the first embodiment of the present invention.

FIG. 5 is a schematic perspective view illustrating the first power module according to the first embodiment of the present invention.

FIG. 6 is a schematic cross-sectional view illustrating the first power module according to the first embodiment of the present invention.

FIG. 7 is a schematic top view illustrating a second power module according to the first embodiment of the present invention.

FIG. 8 is a schematic perspective view illustrating the second power module according to the first embodiment of the present invention.

FIG. 9 is a schematic cross-sectional view illustrating the second power module according to the first embodiment of the present invention.

FIG. 10 is a schematic plan view illustrating a power conversion device according to a second embodiment of the present invention, in which a flow path forming body is omitted.

FIG. 11 is a schematic cross-sectional view illustrating a power conversion device according to a third embodiment of the present invention in a cross section taken along line A-A of FIG. 1.

FIG. 12 is a schematic cross-sectional view illustrating a power conversion device according to a fourth embodiment of the present invention in a cross section taken along line A-A of FIG. 1.

### DESCRIPTION OF EMBODIMENTS

Hereinafter, embodiments of the present invention will be described with reference to the drawings. However, the present invention should not be interpreted as being limited to the following embodiments, and the technical idea of the present invention may be realized by combining other known components. In the drawings, the same elements are denoted by the same reference numerals, and redundant description will be omitted. In the drawings, the U direction is an upward direction, the D direction is a downward direction, the F direction is a forward direction, the B direction is a backward direction, the R direction is a rightward direction, and the L direction is a leftward direction.

### First Embodiment

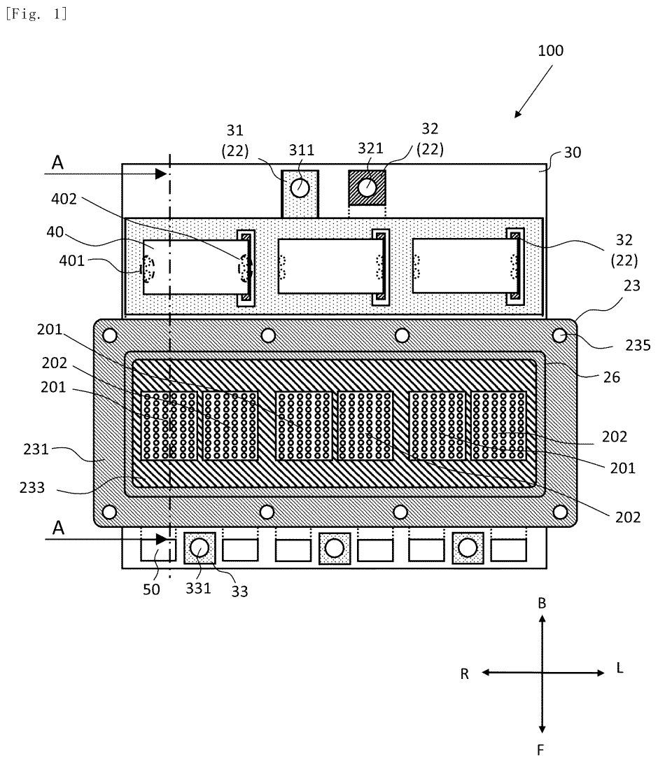

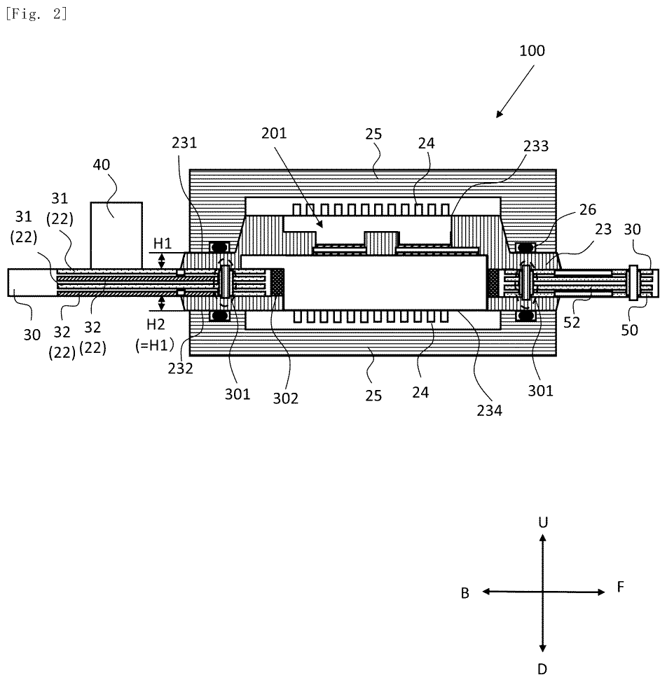

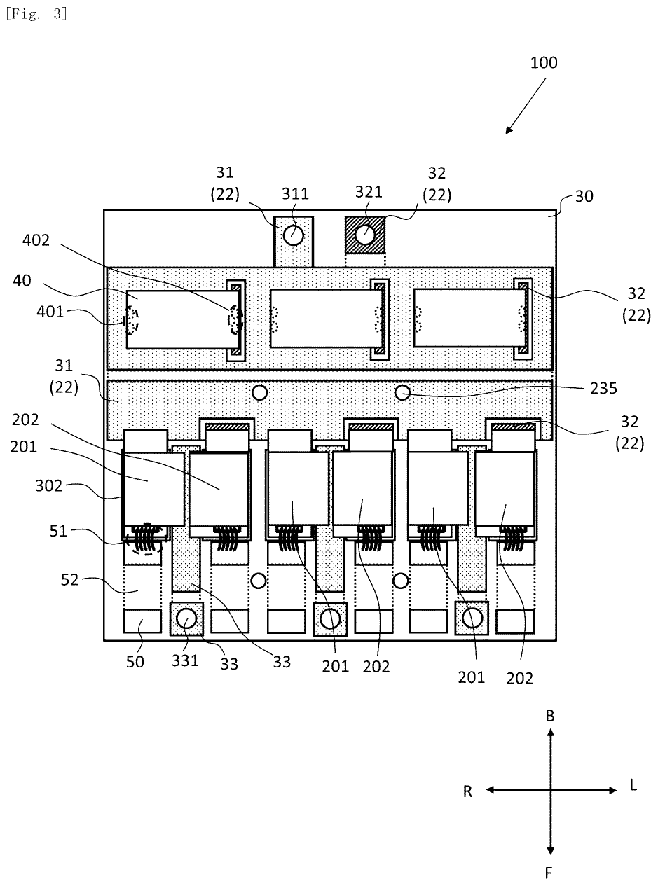

FIG. 1 is a schematic plan view illustrating a power conversion device 100 according to the present embodiment. In FIG. 1, a flow path forming body 25 (see FIG. 2) is not illustrated. FIG. 2 is a schematic cross-sectional view illustrating the power conversion device 100 according to the present embodiment in a cross section taken along line A-A of FIG. 1. FIG. 3 is a schematic plan view illustrating the power conversion device 100 according to the present embodiment. In FIG. 3, a molding resin 23 (see FIG. 2) is not illustrated.

The power conversion device 100 converts DC power from a battery or the like into AC power to be supplied to an electric motor. The power conversion device 100 configures upper arm circuits and lower arm circuits for three phases.

The power conversion device 100 includes circuits for three phases in which circuits for one phase include a first power module 201 constituting an upper arm circuit and a second power module 202 constituting a lower arm circuit.

The power conversion device 100 includes a DC wiring 22 that transmits DC power to the first power module 201 and the second power module 202, an AC output terminal conductor 33, a capacitor 40 that smooths a voltage applied to the power conversion device 100, a control circuit 50 that transmits a control signal, and a circuit board 30 such as a printed circuit board on which all of them are mounted.

In the power conversion device 100, the first power module 201, the second power module 202, and the circuit board 30 are covered and sealed by the molding resin 23. That is, the molding resin 23 covers and seals the first power module 201, the second power module 202, and the circuit board 30 from above and below the circuit board 30.

This eliminates the need for a bus bar having complicated shape, improving productivity.

The first power modules 201 and the second power modules 202, of which the total number is six, are arranged in parallel, when viewed from the direction in which the DC wiring 22 extends in the leftward direction L and the rightward direction R in FIG. 3.

The DC wiring 22 includes a positive electrode power supply terminal conductor 31 through which a current flowing into the circuits for one phase including the first power module 201 and the second power module 202 flows, and a negative electrode power supply terminal conductor 32 through which a current flowing out from the circuits for one phase including the first power module 201 and the second power module 202 flows. The positive electrode power supply terminal conductor 31 and the negative electrode power supply terminal conductor 32 are stacked from the upward direction U to the downward direction D.

The first power module 201 is connected to the positive electrode power supply terminal conductor 31 having a positive electrode power supply terminal 311 and the AC output terminal conductor 33 having an AC output terminal 331. On the other hand, the second power module 202 is connected to the negative electrode power supply terminal conductor 32 having a negative electrode power supply terminal 321 and the AC output terminal conductor 33.

As a result, electric energy necessary for driving the electric motor from the battery is supplied to the first power module 201 and the second power module 202 to control AC power output from the AC output terminal 331 provided in the AC output terminal conductor 33. The first power module 201 and the second power module 202 form circuits for one phase, and this set is provided for three phases and mounted on the circuit board 30. This eliminates the need for a bus bar having a complicated shape, improving productivity.

The circuit board 30 includes a plurality of conductor layers made of a copper material or the like, and the other portion is made of an insulating member such as a glass epoxy resin. In a case where the conductor layers of the circuit board 30 are configured in a four-layer structure, the positive electrode power supply terminal conductor 31, in which the positive electrode power supply terminal 311 is provided, has a main current path on an upper surface and a third inner layer of the circuit board 30, and is connected to the first power module 201 connected to the upper surface of the circuit board 30.

On the other hand, the negative electrode power supply terminal conductor 32, in which the negative electrode power supply terminal 321 is provided, has a main current path on a second inner layer and a lower surface of the circuit board 30, and is connected to the second power module 202 through a via 301 near a portion connected with the second power module 202 connected to the upper surface of the circuit board 30.

In this manner, by virtue of the structure in which the positive electrode power supply terminal conductor 31 and the negative electrode power supply terminal conductor 32 are stacked, the currents flowing through the respective conductors are opposed to each other, and the inductance can be reduced by the magnetic flux canceling effect.

The AC output terminal conductor 33 is formed in each layer through a via (not illustrated), and has an AC output terminal 331 that outputs AC power to the electric motor. As a result, the cross-sectional area of the conductor can be increased, reducing inductance.

A capacitor 40 having a positive electrode terminal 401 and a negative electrode terminal 402 is mounted on the DC wiring 22 outside the flow path forming bodies 25. The positive electrode terminal 401 and the negative electrode terminal 402 are arranged in parallel when viewed from the first power module 201 and the second power module 202. The capacitor 40 includes a film capacitor or the like, and is mounted between the first power module 201 and the second power module 202 and the positive electrode power supply terminal 311 and the negative electrode power supply terminal 321.

This makes it possible to equalize a current path flowing from the capacitor 40 into the first power module 201 and a current path flowing out from the second power module 202 into the capacitor 40, thereby reducing inductance.

The control circuit 50 is connected to a control signal generation circuit (not illustrated), is connected to the first power module 201 and the second power module 202 via a control signal wiring 51 such as wire bonding and an in-board control signal wiring 52, and is arranged adjacent to the other control circuits.

As a result, the inductance of the control signal wiring 51 is reduced, preventing a deterioration in element driving performance, thereby preventing an increase in loss.

The first power module 201 and the second power module 202 are incorporated into a power module incorporating hole 302 in the circuit board 30, and are sealed with the molding resin 23.

The power conversion device 100 includes flow path forming bodies 25 that form flow paths with the circuit board 30 above and below the circuit board 30, respectively, to cool the upper and lower sides of the first power module 201 and the second power module 202 with a refrigerant.

The first power module 201 and the second power module 202 have a first heat dissipation surface 233 on the upper surfaces thereof, and have a second heat dissipation surface 234 on the lower surfaces thereof. The first heat dissipation surface 233 is a surface with which the refrigerant comes into contact, and is formed of the molding resin 23 and an upper surface of the conductor plate. The second heat dissipation surface 234 is a surface with which the refrigerant comes into contact, and is formed of the molding resin 23 and a lower surface of the conductor plate. Heat dissipation fins 24 are disposed on the first heat dissipation surface 233 and the second heat dissipation surface 234. The upper flow path forming body 25 is disposed to cover the first heat dissipation surface 233. The lower flow path forming body 25 is disposed to cover the second heat dissipation surface 234.

### <First Power Module 201>

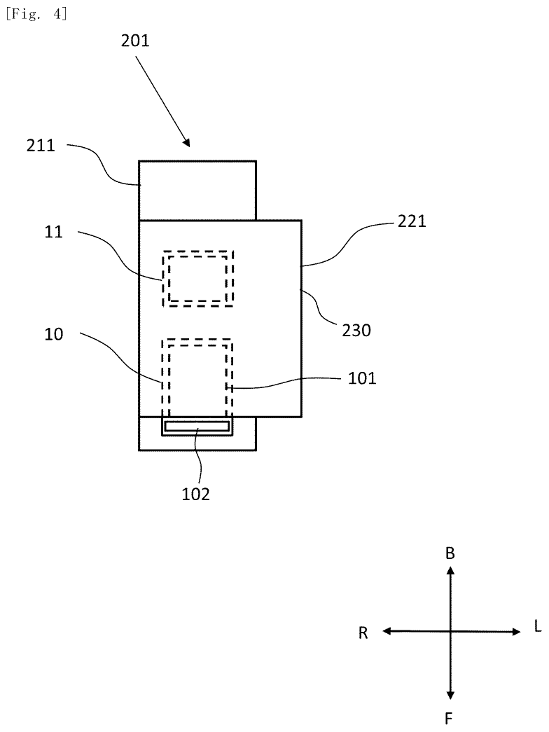

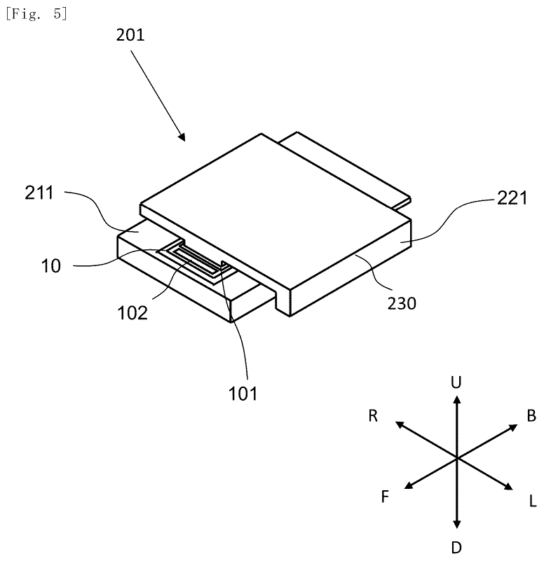

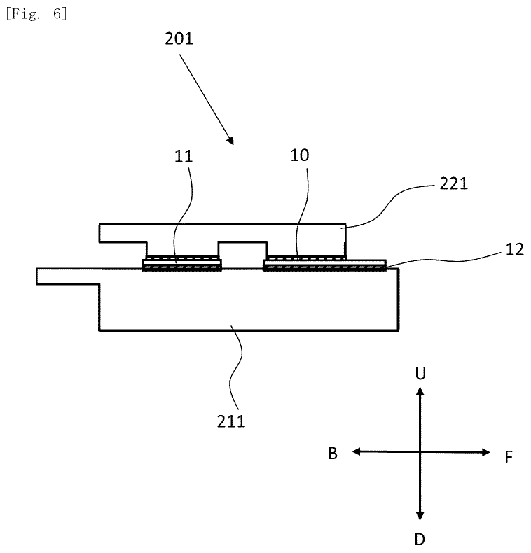

FIG. 4 is a schematic top view illustrating the first power module 201 according to the present embodiment. FIG. 5 is a schematic perspective view illustrating the first power module 201 according to the present embodiment. FIG. 6 is a schematic cross-sectional view illustrating the first power module 201 according to the present embodiment.

The first power module 201 constitutes an upper arm circuit for one phase in the power conversion device 100 that converts DC power into AC power. The first power module 201 includes an IGBT 10, a diode 11, a first collector conductor plate 211 disposed below the IGBT 10 and the diode 11, and a first emitter conductor plate 221 disposed above the IGBT 10 and the diode 11.

The first collector conductor plate 211 and the first emitter conductor plate 221 have one or less bent portion 230. The first collector conductor plate 211 and the first emitter conductor plate 221 are connected to the DC wiring 22 on the circuit board 30. More specifically, the first collector conductor plate 211 extends linearly from a portion of the first collector conductor plate 211 protruding on the circuit board 30 without a bent portion, and is connected to the DC wiring 22 on the circuit board 30. The first emitter conductor plate 221 extends in the leftward direction L from a portion of the first emitter conductor plate 221 protruding on the circuit board 30, is then bent in the downward direction D via one bent portion 230, and is connected to the DC wiring 22 on the circuit board 30.

The IGBT 10 has a plate-shaped main electrode 101 and a control electrode 102 that controls a main current flowing through the main electrode 101. The IGBT 10 and the diode 11 are sandwiched between the first collector conductor plate 211 and the first emitter conductor plate 221 from both sides. The IGBT 10 and the diode 11 are connected to the first collector conductor plate 211 and the first emitter conductor plate 221 via a metal bonding material 12 such as solder. The first collector conductor plate 211 and the first emitter conductor plate 221 are made of a copper material.

### <Second Power Module 202>

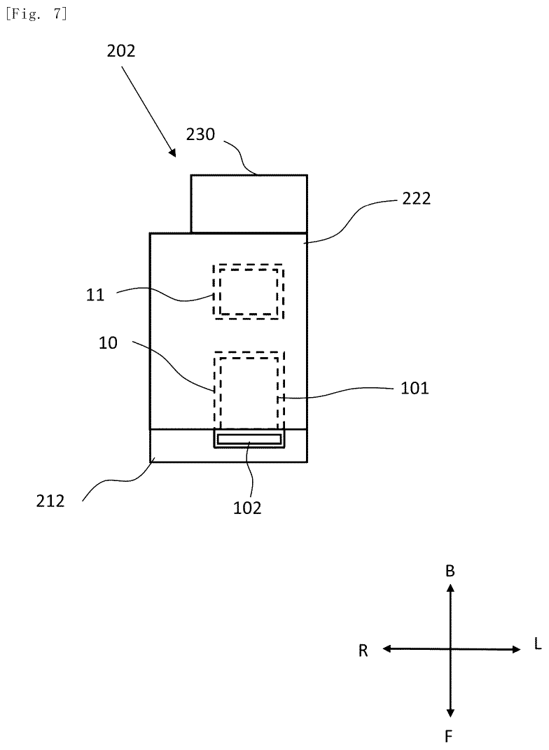

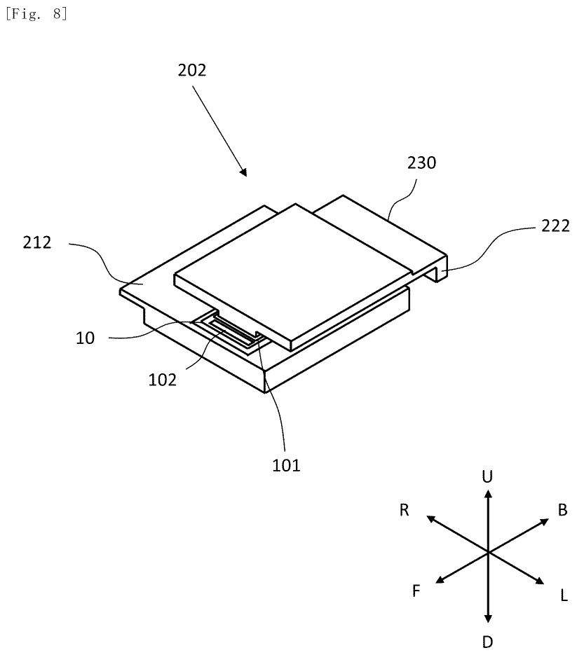

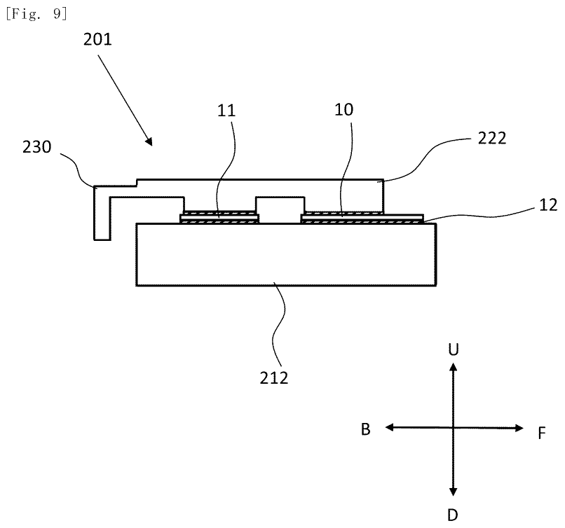

FIG. 7 is a schematic top view illustrating the second power module 202 according to the present embodiment. FIG. 8 is a schematic perspective view illustrating the second power module 202 according to the present embodiment. FIG. 9 is a schematic cross-sectional view illustrating the second power module 202 according to the present embodiment.

The second power module 202 constitutes a lower arm circuit for one phase in the power conversion device 100 that converts DC power into AC power. The second power module 202 includes an IGBT 10, a diode 11, a second collector conductor plate 212 disposed below the IGBT 10 and the diode 11, and a second emitter conductor plate 222 disposed above the IGBT 10 and the diode 11.

The second collector conductor plate 212 and the second emitter conductor plate 222 have one or less bent portion 230. The second collector conductor plate 212 and the second emitter conductor plate 222 are connected to the DC wiring 22 on the circuit board 30. More specifically, the second collector conductor plate 212 extends linearly from a portion of the second collector conductor plate 212 protruding on the circuit board 30 without a bent portion, and is connected to the DC wiring 22 on the circuit board 30. The second emitter conductor plate 222 extends in the backward direction B from a portion of the second emitter conductor plate 222 protruding on the circuit board 30, is then bent in the downward direction D via one bent portion 230, and is connected to the DC wiring 22 on the circuit board 30.

The IGBT 10 and the diode 11 are sandwiched between the second collector conductor plate 212 and the second emitter conductor plate 222 from both sides. The IGBT 10 and the diode 11 are connected to the second collector conductor plate 212 and the second emitter conductor plate 222 via a metal bonding material 12 such as solder. The second collector conductor plate 212 and the second emitter conductor plate 222 are made of a copper material. The second emitter conductor plate 222 extends in the horizontal direction from a portion of the second emitter conductor plate 222 protruding on the circuit board 30, is then bent in the downward direction D via one bent portion, and is connected to the DC wiring 22 on the circuit board 30.

### <Features of Molding Resin 23>

Returning to FIGS. 1 to 3, the molding resin 23 has a first seal surface portion 231 formed to surround all of the three first power modules 201 and the three second power modules 202 on the upper side of the circuit board 30, and a second seal surface portion 232 formed to surround all of the three first power modules 201 and the three second power modules 202 on the lower side of the circuit board 30.

A seal surface portion of the upper flow path forming body 25 abuts on the first seal surface portion 231 formed around the plurality of power modules 201 and 202. A seal surface portion of the lower flow path forming body 25 abuts on the second seal surface portion 232 formed around the plurality of power modules 201 and 202. A seal groove is formed in the seal surface portion of the upper flow path forming body 25, and an O-ring 26, which is a seal member for sealing between the upper flow path forming body 25 and the first seal surface portion 231, is disposed in the seal groove. Similarly, a seal groove is formed in the seal surface portion of the lower flow path forming body 25, and an O-ring 26, which is a seal member for sealing between the lower flow path forming body 25 and the second seal surface portion 232, is disposed in the seal groove.

The first seal surface portion 231 and the second seal surface portion 232 of the molding resin is thinner than the regions of the molding resin 23 sealing the first power module 201 and the second power module 202. The first seal surface portion 231 is formed to be thinner than the portion of the molding resin 23 where the first heat dissipation surface 233 is formed. The second seal surface portion 232 is formed to have substantially the same thickness as the portion of the molding resin 23 where the second heat dissipation surface 234 is formed.

The first seal surface portion 231 is formed on the circuit board 30. The second seal surface portion 232 is formed on a side opposite to the first seal surface portion 231 with respect to the circuit board 30. A thickness H1 of the first seal surface portion 231 and a thickness H2 of the second seal surface portion 232 are formed to be equal (H1=H2) with respect to the circuit board 30.

The first seal surface portion 231 and the second seal surface portion 232 are formed in the same shape, overlapping each other with respect to the circuit board 30 in a thickness direction. Therefore, since the first seal surface portion 231 and the second seal surface portion 232 have the same thickness with respect to the circuit board 30, the first seal surface portion 231 and the second seal surface portion 232 are formed to have the same volume.

The first seal surface portion 231 and the second seal surface portion 232 protrude from the circuit board 30 on both sides (the leftward direction L and the rightward direction R in FIG. 1) in a direction in which the first power modules 201 and the second power modules 202, of which the total number is six, are arranged in parallel.

This makes it possible to equalize volumes in the first seal surface portion 231 and the second seal surface portion 232 of the molding resin 23 at the peripheral edge of the molding resin 23 where the first power module 201 and the second power module 202 are not arranged. Therefore, it is possible to make the amount of shrinkage of the molding resin 23 when hardened at room temperature uniform, thereby suppressing warpage. As a result, the process of polishing the first seal surface portion 231 and the second seal surface portion 232 is eliminated, improving manufacturability.

The first seal surface portion 231 and the second seal surface portion 232 have a flow path forming body holding portion 235 at peripheral edge portions. The molding resin 23 is held by the two flow path forming bodies 25 to surround the first power modules 201 and the second power modules 202. The control signal wiring 51 is also formed inside the flow path forming body 25. Here, the capacitor 40 and the control circuit 50 are not included in the flow path forming body 25.

The two flow path forming bodies 25, each having the O-ring 26, are fastened above and below the circuit board 30 by a holding part such as a screw used for the flow path forming body holding portion 235. As a result, the size of the flow path forming body 25 can be reduced as compared with that in a case where a fastening portion is provided on the circuit board 30. In addition, it is possible to form a highly airtight flow path without being affected by steps caused by the conductor layers of the circuit board 30.

The first seal surface portion 231 and the second seal surface portion 232 of the molding resin 23 are formed as glossy surfaces. This increases the adhesion between the first seal surface portion 231 and the second seal surface portion 232 and the O-rings 26, improving the airtightness.

Surfaces of the molding resin 23 other than the seal surface portions are formed as matte surfaces. This makes it easy to remove the molding resin 23 from a molding die when it is formed.

In the circuit board 30, a conductor layer is not disposed on a surface bonded to the molding resin 23, and a conductor is connected to the peripheral edge portion of the molding resin 23 via an in-board wiring. This prevents a resin leakage when the molding resin 23 is formed, improving manufacturability.

The heat dissipation fins 24 are formed on the upper and lower surfaces of the first power module 201 and the second power module 202. This makes it possible to form a heat dissipation path from the semiconductor elements of the first power module 201 and the second power module 202 to the heat dissipation fins 24 without passing through an insulating member. In addition, the semiconductor elements of the first power module 201 and the second power module 202 to the heat dissipation fins 24 are directly cooled by the refrigerant such as oil, suppressing an increase in thermal resistance, thereby making it possible to increase the output of the power conversion device.

Since the capacitor 40 and the control circuit 50 are not included in the flow path forming body 25, it is possible to prevent the electronic component from being corroded due to the contact of the refrigerant. On the other hand, the first power module 201 and the second power module 202, and the control signal wiring 51 are formed inside the flow path forming body 25. However, the first power module 201 and the second power module 202, and the control signal wiring 51 are not electrically affected by the contact of the molding resin 23 with the refrigerant. The control signal wiring 51 is connected to the control circuit 50 via an in-board control signal wiring 52 provided in the circuit board 30.

### Effects of Present Embodiment

As described above, in the present embodiment, the volumes in the first seal surface portion 231 and the second seal surface portion 232 of the molding resin 23 on and under the circuit board 30 are equal at the peripheral edge of the molding resin 23. This makes it possible to make the amount of shrinkage of the molding resin 23 when hardened at room temperature uniform, thereby suppressing warpage. As a result, the process of polishing the first seal surface portion 231 and the second seal surface portion 232 can be eliminated, improving the manufacturability of the power conversion device 100. Furthermore, the heat dissipation fins 24 are provided on the upper and lower surfaces of the first power module 201 and the second power module 202, and the semiconductor elements of the first power module 201 and the second power module 202 to the heat dissipation fins 24 are directly cooled by the refrigerant such as oil, thereby improving cooling performance.

### Second Embodiment

In the present embodiment, the elements that are the same as those in the above-described embodiment will be denoted by the same reference numerals, and redundant description will be omitted.

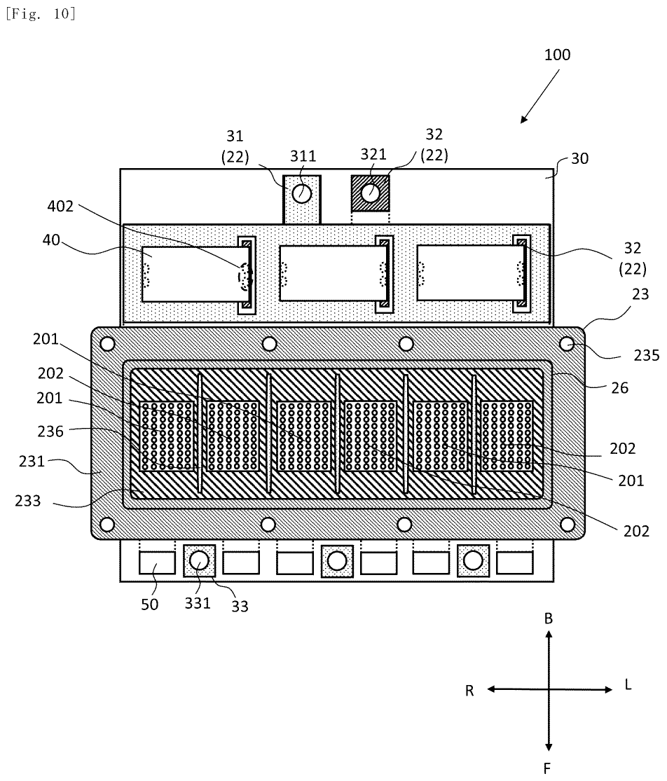

FIG. 10 is a schematic plan view illustrating a power conversion device 100 according to the present embodiment. In FIG. 10, a flow path forming body 25 is not illustrated. Between the power modules 201 and 202, slits 236 are formed in the first heat dissipation surface 233 and the second heat dissipation surface 234 of the molding resin 23. This enhances the warpage suppressing effect when the molding resin 23 is hardened at room temperature, improving the manufacturability of the power conversion device 100.

### Third Embodiment

In the present embodiment, the elements that are the same as those in the above-described embodiment will be denoted by the same reference numerals, and redundant description will be omitted.

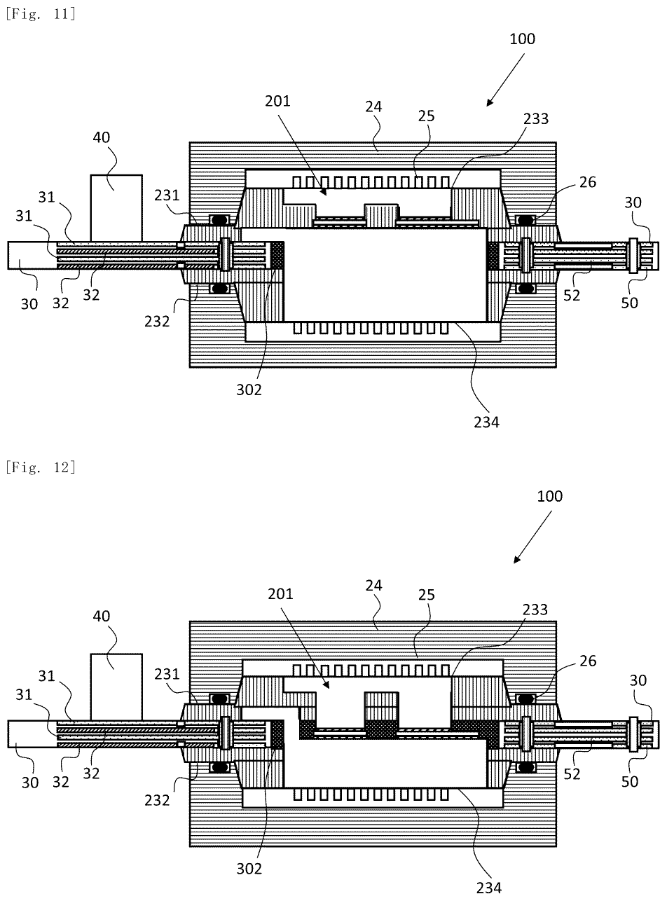

FIG. 11 is a schematic cross-sectional view illustrating a power conversion device 100 according to the present embodiment in a cross section taken along line A-A of FIG. 1. The molding resin 23 is formed to have the same thickness from the circuit board 30 to the first heat dissipation surface 233 and the second heat dissipation surface 234. Therefore, in the present embodiment, the first collector conductor plate 211 of the first power module 201 is higher than that in the first embodiment. This enhances the warpage suppressing effect when the molding resin 23 is hardened at room temperature, improving the manufacturability of the power conversion device 100.

### Fourth Embodiment

In the present embodiment, the elements that are the same as those in the above-described embodiment will be denoted by the same reference numerals, and redundant description will be omitted.

FIG. 12 is a schematic cross-sectional view illustrating a power conversion device 100 according to the present embodiment in a cross section taken along line A-A of FIG. 1. The thicknesses of the molding resin 23 from the IGBT 10 and the diode 11 to the first heat dissipation surface 233 and to the second heat dissipation surface 234 are formed to be equal. This enhances the warpage suppressing effect when the molding resin 23 is hardened at room temperature, improving the manufacturability of the power conversion device 100.

### Effects of Differences

### (A)

The power conversion device 100 includes a first power module 201 and a second power module 202 that convert DC power into AC power. The power conversion device 100 includes a DC wiring 22 that transmits DC power to the first power module 201 and the second power module 202. The power conversion device 100 includes a circuit board 30 on which the first power module 201 and the second power module 202 are arranged and the DC wiring 22 is mounted. The power conversion device 100 includes a molding resin 23 that covers and seals the first power module 201, the second power module 202, and the circuit board 30. The molding resin 23 has a first seal surface portion 231 and a second seal surface portion 232 around the first power module 201 and the second power module 202. The first seal surface portion 231 and the second seal surface portion 232 are thinner than regions sealing the first power module 201 and the second power module 202.

In this configuration, by equalizing volumes in the first seal surface portion 231 and the second seal surface portion 232 of the molding resin 23 on and under the circuit board 30 at a peripheral edge of the molding resin 23 where the first power module 201 and the second power module 202 are not arranged, it is possible to make the amount of shrinkage of the molding resin 23 when hardened at room temperature uniform, thereby suppressing warpage. As a result, the process of polishing the first seal surface portion 231 and the second seal surface portion 232 is eliminated, improving manufacturability. In addition, since the upper and lower sides of the circuit board 30 are covered with the molding resin 23, both sides of the first power module 201 and the second power module 202 can be cooled. By cooling both sides of the first power module 201 and the second power module 202, cooling performance can be improved, while suppressing an occurrence of warpage of the sealing resin when hardened at room temperature.

### (B)

The seal surface portions 231 and 232 includes a first seal surface portion 231 formed on the circuit board 30 and a second seal surface portion 232 formed on a side opposite to the first seal surface portion 231 with respect to the circuit board 30. The first seal surface portion 231 and the second seal surface portion 232 are formed to have the same thickness with respect to the circuit board 30.

In this configuration, by equalizing volumes in the first seal surface portion 231 and the second seal surface portion 232 of the molding resin 23 at a peripheral edge of the molding resin 23 where the first power module 201 and the second power module 202 are not arranged, it is possible to make the amount of shrinkage of the molding resin 23 when hardened at room temperature uniform in the first seal surface portion 231 and the second seal surface portion 232, thereby suppressing warpage.

### (C)

The plurality of power modules 201 and 202 include circuits for three phases in which circuits for one phase include a first power module 201 constituting an upper arm circuit and a second power module 202 constituting a lower arm circuit. The plurality of power modules 201 and 202 are arranged in parallel when viewed from a direction in which the DC wiring 22 extends.

In this configuration, six power modules 201 and 202 can be aligned, and the seal surface portions 231 and 232 of the molding resin 23 can be configured in a simple shape.

### (D)

Between the power modules 201 and 202, slits 236 are formed in the first heat dissipation surface 233 and the second heat dissipation surface 234 of the molding resin 23.

In this configuration, six power modules 201 and 202 can be aligned, and a non-contact state between the power modules 201 and 202 can be maintained.

The power conversion device 100 includes flow path forming bodies 25 that form flow paths with the circuit board 30 above and below the circuit board 30, respectively, to cool upper and lower sides of the plurality of power modules 201 and 202 with a refrigerant.

In this configuration, since the flow path forming bodies 25 are provided above and below the circuit board 30 covered with the molding resin 23, both sides of all the power modules 201 and 202 can be cooled.

### (E)

The power conversion device 100 includes a flow path forming body holding portion 235 that holds the flow path forming bodies 25 at peripheral edge portions of the seal surface portions 231 and 232.

In this configuration, the size of the flow path forming body 25 can be reduced as compared with that in a case where a fastening portion for fastening the flow path forming body 25 is provided on the circuit board 30.

### (F)

The seal surface portions 231 and 232 of the molding resin 23 are glossy surfaces. Surfaces of the molding resin 23 other than the seal surface portions 231 and 232 are matte surfaces.

In this configuration, since the seal surface portions 231 and 232 are glossy surfaces, the adhesion between the first seal surface portion 231 and the second seal surface portion 232 and the seal members such as O-rings 26 is increased, thereby improving the airtightness. Since surfaces other than the seal surface portions 231 and 232 are matte surfaces, the molding resin 23 can be easily removed from a molding die when it is formed.

### (G)

The DC wiring 22 includes a positive electrode power supply terminal conductor 31 through which a current flowing into circuits for one phase including two of the power modules 201 and 202 flows, and a negative electrode power supply terminal conductor 32 through which a current flowing out from circuits for one phase including two of the power modules 201 and 202 flows. The positive electrode power supply terminal conductor 31 and the negative electrode power supply terminal conductor 32 are stacked.

In this configuration, the positive electrode power supply terminal conductor 31 and the negative electrode power supply terminal conductor 32 have a stack structure, and currents flowing through the respective conductor layers are opposed to each other, so that a magnetic flux canceling effect is exhibited, thereby reducing inductance.

### (H)

A capacitor 40 having a positive electrode terminal 401 and a negative electrode terminal 402 is mounted on the DC wiring 22 outside the flow path forming bodies 25. The positive electrode terminal 401 and the negative electrode terminal 402 are arranged in parallel when viewed from the plurality of power modules 201 and 202.

In this configuration, it is possible to equalize a current path flowing from the capacitor 40 into one power module 201 and a current path flowing out from the other power module 202 forming a pair to the capacitor 40, thereby reducing inductance.

### (I)

The molding resin 23 covers and seals the plurality of power modules 201 and 202 and the circuit board 30 from above and below the circuit board 30.

In this configuration, the flow path forming bodies 25 can be disposed above and below the circuit board 30 covered with the molding resin 23, and cooling performance can be improved by cooling both sides of the power modules 201 and 202. In addition, since the upper and lower sides of the circuit board 30 are covered with the molding resin 23, it is possible to suppress an occurrence of warpage of the sealing resin when hardened at room temperature.

### (J)

The first seal surface portion 231 and the second seal surface portion 232 are formed in the same shape, overlapping each other with respect to the circuit board 30 in a thickness direction.

In this configuration, by forming the first seal surface portion 231 and the second seal surface portion 232 of the molding resin 23 to have the same shape and the same thickness at the peripheral edge of the molding resin 23 where the power modules 201 and 202 are not arranged, it is possible to equalize volumes.

### (K)

The first seal surface portion 231 and the second seal surface portion 232 are formed to have the same volume.

In this configuration, since the first seal surface portion 231 and the second seal surface portion 232 have the same volume, it is possible to make the amount of shrinkage of the molding resin 23 when hardened at room temperature uniform in the first seal surface portion 231 and the second seal surface portion 232, thereby suppressing warpage.

### (L)

The seal surface portions 231 and 232 protrude from the circuit board 30 on both sides in a direction in which the plurality of power modules 201 and 202 are arranged in parallel.

In this configuration, the molding resin 23 protruding from the circuit board 30 is connected to the upper and lower sides of the circuit board 30, and the molding resin 23 can be formed as one body.

### (M)

Each of the plurality of power modules 201 and 202 includes an IGBT 10, a diode 11, a collector conductor plate 211 or 212 disposed below the IGBT 10 and the diode 11, and an emitter conductor plate 221 or 222 disposed above the IGBT 10 and the diode 11. The collector conductor plate 211 or 212 and the emitter conductor plate 221 or 222 have one or less bent portion 230. The collector conductor plate 211 or 212 and the emitter conductor plate 221 or 222 are connected to the DC wiring 22 on the circuit board 30.

In this configuration, the number of bent portions 230 of the collector conductor plates 211 and 212 and the emitter conductor plates 221 and 222 is small, improving manufacturability.

### (N)

The collector conductor plate 211 or 212 extends linearly from a portion of the collector conductor plate 211 or 212 protruding on the circuit board 30 without a bent portion, and is connected to the DC wiring 22 on the circuit board 30.

In this configuration, there is no bent portion of the collector conductor plate 211 or 212, improving manufacturability.

### REFERENCE SIGNS LIST

10 IGBT
11 diode
12 metal bonding material
22 DC wiring
23 molding resin
24 heat dissipation fin
25 flow path forming body
26 O-ring
30 circuit board
31 positive electrode power supply terminal conductor
32 negative electrode power supply terminal conductor
33 AC output terminal conductor
40 capacitor
50 control circuit
51 control signal wiring
52 in-board control signal wiring
100 power conversion device
101 main electrode
102 control electrode
201 first power module
202 second power module
211 first collector conductor plate
212 second collector conductor plate
221 first emitter conductor plate
222 second emitter conductor plate
230 bent portion
231 first seal surface
232 second seal surface
233 first heat dissipation surface
234 second heat dissipation surface
235 flow path forming body holding portion
236 slit
301 via
302 power module incorporating hole
311 positive electrode power supply terminal
321 negative electrode power supply terminal
331 AC output terminal
401 positive electrode terminal
402 negative electrode terminal

1. A power conversion device comprising:
a plurality of power modules which convert DC power into AC power;
a DC wiring which transmits DC power to the plurality of power modules;
a circuit board on which the plurality of power modules are arranged and the DC wiring is mounted; and
a molding resin which covers and seals the plurality of power modules and the circuit board,
wherein the molding resin has seal surface portions around the plurality of power modules, and
the seal surface portions are thinner than regions sealing the plurality of power modules.

2. The power conversion device according to claim 1, wherein
the seal surface portions include a first seal surface portion formed on the circuit board and a second seal surface portion formed on a side opposite to the first seal surface portion with respect to the circuit board, and
the first seal surface portion and the second seal surface portion are formed to have the same thickness with respect to the circuit board.

3. The power conversion device according to claim 1, wherein
the plurality of power modules include circuits for three phases in which circuits for one phase include a first power module constituting an upper arm circuit and a second power module constituting a lower arm circuit, and
the plurality of power modules are arranged in parallel when viewed from a direction in which the DC wiring extends.

4. The power conversion device according to claim 3, wherein slits are formed in the molding resin between the power modules.

5. The power conversion device according to claim 1, further comprising flow path forming bodies which form flow paths with the circuit board above and below the circuit board, respectively, to cool upper and lower sides of the plurality of power modules with a refrigerant.

6. The power conversion device according to claim 5, further comprising a flow path forming body holding portion which holds the flow path forming bodies at peripheral edge portions of the seal surface portions.

7. The power conversion device according to claim 1, wherein
the seal surface portions of the molding resin are glossy surfaces, and
surfaces other than the seal surface portions of the molding resin are matte surfaces.

8. The power conversion device according to claim wherein
the DC wiring includes a positive electrode power supply terminal conductor through which a current flowing into circuits for one phase including two of the power modules flows, and a negative electrode power supply terminal conductor through which a current flowing out from circuits for one phase including two of the power modules flows, and
the positive electrode power supply terminal conductor and the negative electrode power supply terminal conductor are stacked.

9. The power conversion device according to claim 5, wherein
a capacitor having a positive electrode terminal and a negative electrode terminal is mounted on the DC wiring outside the flow path forming bodies, and
the positive electrode terminal and the negative electrode terminal are arranged in parallel when viewed from the plurality of power modules.

10. The power conversion device according to claim 1, wherein the molding resin covers and seals the plurality of power modules and the circuit board from above and below the circuit board.

11. The power conversion device according to claim 2, wherein the first seal surface portion and the second seal surface portion are formed in the same shape, overlapping each other with respect to the circuit board in a thickness direction.

12. The power conversion device according to claim 11, wherein the first seal surface portion and the second seal surface portion are formed to have the same volume.

13. The power conversion device according to claim 3, wherein the seal surface portions protrude from the circuit board on both sides in a direction in which the plurality of power modules are arranged in parallel.

14. The power conversion device according to claim 1, wherein
each of the plurality of power modules includes an IGBT, a diode, a collector conductor plate disposed below the IGBT and the diode, and an emitter conductor plate disposed above the IGBT and the diode,
the collector conductor plate and the emitter conductor plate have one or less bent portion, and
the collector conductor plate and the emitter conductor plate are connected to the DC wiring on the circuit board.

15. The power conversion device according to claim 14, wherein the collector conductor plate extends linearly from a portion of the collector conductor plate protruding on the circuit board without a bent portion, and is connected to the DC wiring on the circuit board.
